(19) United States
(12) Patent Application Publication
(10) Pub. No.: US 2013/0307097 A1
(43) Pub. Date: Nov. 21, 2013

(54) Magnetoresistive random access memory cell design

(71) Applicants: Ge Yi, San Ramon, CA (US); Shaoping Li, San Ramon, CA (US); Yunjun Tang, Pleasanton, CA (US); Zongrong Liu, Pleasanton, CA (US); Dujiang Wan, Fremont, CA (US)

(72) Inventors: Ge Yi, San Ramon, CA (US); Shaoping Li, San Ramon, CA (US); Yunjun Tang, Pleasanton, CA (US); Zongrong Liu, Pleasanton, CA (US); Dujiang Wan, Fremont, CA (US)

(21) Appl. No.: 13/472,085

(22) Filed: May 15, 2012

(51) Int. Cl. H01L 29/82

(52) U.S. Cl. 257/421; 257/E29.323

(57) ABSTRACT

A magnetic memory cell comprises in-plane anisotropy tunneling magnetic junction (TMJ) and two fixed in-plane storage-stabilized layers, which splits on the both side of the data storage layer of the TMJ. The magnetizations of the said fixed in-plane storage-stabilized layers are all normal to that of the reference layer of TMJ but point to opposite direction. The existing of the storage-stabilized layers not only enhances the stability of the data storage, but also can reduce the critical current needed to flip the data storage layer via some specially added features.

### REFERENCE CITED—U.S. PATENT DOCUMENTS

[1] J. C. Slonczewski, J. Magn. Magn. Mater. 159, (1996) L1.

[2] L. Berger, Phys. Review B 54 (1996) 9353.

[3] M. Hosomi et al., 2005 IEDM Technical Digest (2005) p459.

[4] D. Heim and S. S. P. Parkin, U.S. Pat. No. 5,465,185 “Magnetoresistive spin valve sensor with improved pinned ferromagnetic layer and magnetic recording system using the sensor”.

[5] S. S. P. Parkin and D. Heim, Phys. Review. B 44 (1991) 7131.

[6] S. Ikeda et al., Nature Materials, 9 (2010) 721 “A perpendicular-anisotropy CoFeB-MgO magnetic tunnel junction”.

[7] H. Liu et. Al., Appl. Phys. Lett., 97 (2010) 242510 “Ultrafast switching in magnetic tunneling junction based orthogonal spin transfer devices”.

[8] A. D. Kent et. Al., Appl. Phys. Lett., 84 (2004) 3897 “Spin-transfer-induced precessional magnetization reversal”.

[9] A. D. Ken and B. Ozyilmaz, U.S. Pat. No. 7,986,544 B2 “Electronic Devices Based on Current Induced Magnetization Dynamics in Single Magnetic Layers”.

[10] H. Meng et al., Appl. Phys. Lett., 100 (2012) 122405 “Eletcric field effects in low resistance CoFeB-MgO magnetic tunneling junctions with perpendicular anisotropy”

[11] C. Fowley et. Al., IEEE Trans. Mag. 46 (2010) 2116 “Perpendicular Magnetic Anisotropy in CoFeB/Pd Bilayers”.

[12] A. Ken et. al., US 2006/0030058 A1 “High Speed Low Power magnetic Devices Based on Current Induced Spin-Momentum Transfer”

[13] M. Nakayama et. al., J. Appl. Phys. 103 (2008) 07A710, “Spin transfer switching in TbCoFe/CoFeB/MgO/CoFeB/TbCoFe magnetic tunnel junctions with perpendicular magnetic anisotropy”.

[14] C-T Yen and Y-H. Wang, U52011/0241139 A1, “Magnetic Random Access Memory”.

[15] C-T Yen et. al, Appl. Phys. Lett. 93 (2008) 092504, “Reduction in critical current density for spin torque transfer switching with composite free layer”

[16] Meng-Shian Lin and Chih-Huang Lai, J. Appl. Phys. 101, (2007) 09D121, “Perpendicular interlayer coupling through oscillatory Ruderman-Kittel-Kasuya-Yosida interaction between Co/Pt multilayers and Co/TbCo bilayers”

[17] Shaoping Li and C. Potter, U.S. Pat. No. 6,731,473 B2 “Dual Pseudo Spin Valve Heads”

### FIELD OF INVENTION

The invention is related to memory cell design for magnetoresistive random access memory (MRAM), more specifically a memory cell comprising two in-plane magnetic stabilization enhancement layers locating on opposite side of the data storage layer of an in-plane anisotropy TMR sensing stack structure. The magnetizations of the stability enhancement layers are normal to the magnetic reference layer of MTJ and point to opposite directions. There is also a switching current spin polarization layer built within the stack to reduce the switching current needed to flip the data storage layer.

### BACKGROUND ART

Data storage memory is one of the backbones of the modern information technology. Semiconductor memory in the form of DRAM, SRAM and flash memory has dominated the digital world for the last forty years. Comparing to DRAM based on transistor and capacitor above the gate of the transistor, SRAM using the state of a flip-flop with large form factor is more expensive to produce but generally faster and less power consumption. Nevertheless, both DRAM and SRAM are volatile memory, which means they lost the information stored once the power is removed. Flash memory on the other hand is non-volatile memory and cheap to manufacture. However, flash memory has limited endurances of writing cycle and slow write through the read is relatively faster.

MRAM is a relatively a new type of memory technologies. It has the speed of the SRAM, density of the DRAM and it is non-volatile as well. If it is used to replace the DRAM in computer, it will not only give “instant on” but “always-on” status for operation system and restore the system to the point when the system is power off last time. It could provide a single storage solution to replace separate cache (SRAM), memory (DRAM) and permanent storage (HDD or flash-based SSD) on portable device at least. Considering the growth of “cloud computing”, MRAM has a great potential and can be the key dominated technology in digital world.

MRAM storage the informative bit “1” or “0” into the two magnetic states in the so-called magnetic storage layer. The different states in the storage layer gives two distinctive voltage outputs from the whole memory cell, normally a patterned TMR or GMR stack structures. The TMR or GMR stack structures provide a read out mechanism sharing the same well-understood physics as current magnetic reader used in conventional hard disk drive.

There are two kinds of the existing MRAM technologies based on the write process: one kind, which can be labeled as the conventional magnetic field switched (toggle) MRAM, uses the magnetic field induced by the current in the remote write line to change the magnetization orientation in the data stored magnetic layer from one direction (for example “1”) to another direction (for example “0”). This kind of MRAM has more complicated cell structure and needs relative high write current (in the order of mA). It also has poor scalability beyond 65 nm because the write current in the write line needs to continue increase to ensure reliable switching the magnetization of a dimension shrinking magnetic stored layer because of the smaller the physical dimension of the storage layer, the higher the coercivity it normally has for the same materials. Nevertheless, the only commercially available MRAM so far is still based on this conventional writing scheme. The other class of the MRAM is called spin-transfer torque (STT) switching MRAM. It is believed that the STT-RAM has much better scalability due to its simple memory cell structure. While the data read out mechanism is still based on TMR effect, the data write is governed by physics of spin-transfer effect [1, 2]. Despite of intensive efforts and investment, even with the early demonstrated by Sony in late 2005 [3], no commercial products are available on the market so far. One of the biggest challenges of STT-RAM is its reliability, which depends largely on the value and statistical distribution of the critical current density needed to flip the magnetic storage layers within the every patterned TMR stack used in the MRAM memory structures. Currently, the value of the critical current density is still in the range of 10⁶ A/cm². To allow such a large current density through the dielectric barrier layer such as AlOx and MgO in the TMR stack, the thickness of the barrier has to be relatively thin, which not only limits the magnetoresist (MR) ratio value but also cause potential risk of the barrier breakdown. As such, a large portion of efforts in the STT-RAM is focused on lower the critical current density while still maintaining the thermal stability of the magnetic data storage layer. Another challenge is related partially to the engineering challenge due to the imperfection of memory cell structure patterning (patterned TMR element) such as edge magnetic moment damage and size variation, as well as uniformity of the barrier thickness during the deposition and magnetic uniformity in the data storage layer and spin polarized magnetic layer (also called reference layer). This non-uniformity leads to variation of the size, edge roughness, magnetic uniformity and barrier thickness for patterned TMR elements, which ultimately cause the statistic variation of critical current density needed for each patterned cell.

The success of the STT-RAM largely depends on the breakthrough on the material used in STT-RAM, which give a fair balance between the barrier thickness (related to broken down voltage and TMR ratio), critical current density and thermal stability of the magnetic storage layer. Currently, Based on the anisotropy of the data storage layer, the STT-RAM can be classified into in-plane anisotropy cell and perpendicular cell. The in-plane anisotropy cell has much high magnetoresistance value (MR value) than that of the perpendicular cell but suffers from the thermal stability issue when the size of the cell is reduced, particularly when the magnetization of the storage layer (SL) is parallel to the fixed reference magnetic layer (RL), the magnetostatic coupling between the SL and RL will low the energy barrier and cause large noise or even SL flips.

In this invention, we propose a stabilization scheme to enhance the thermal stability of in-plane MRAM cell with spin-polarization layer, which could also low the critical current needed to flip the data storage layer.

### SUMMARY OF THE INVENTION

The present invention of the proposed memory cells for MRAM to enhance the thermal stability while maintaining low switching current, which comprises an in-plane anisotropy magnetic tunneling junction (MTJ), two within stack magnetic stabilization layers whose magnetization point to opposite direction and all normal to the that of the reference layer of the MTJ as well as spin polarization layer for switching current.

### BRIEF DESCRIPTION OF THE DRAWINGS

FIG. 1 illustrates one of the embodiments of proposed magnetic memory cell.

FIG. 2 illustrates one of the embodiments of proposed magnetic memory cell with spin polarization layer.

FIG. 3 Illustrates one of the embodiments of proposed magnetic memory cell with synthetic antiferromagnetic spin polarization layer.

### DETAILED DESCRIPTION

The following description is provided in the context of particular designs, applications and the details, to enable any person skilled in the art to make and use the invention. However, for those skilled in the art, it is apparent that various modifications to the embodiments shown can be practiced with the generic principles defined here, and without departing the spirit and scope of this invention. Thus, the present invention is not intended to be limited to the embodiments shown, but is to be accorded the widest scope consistent with the principles, features and teachings disclosed here.

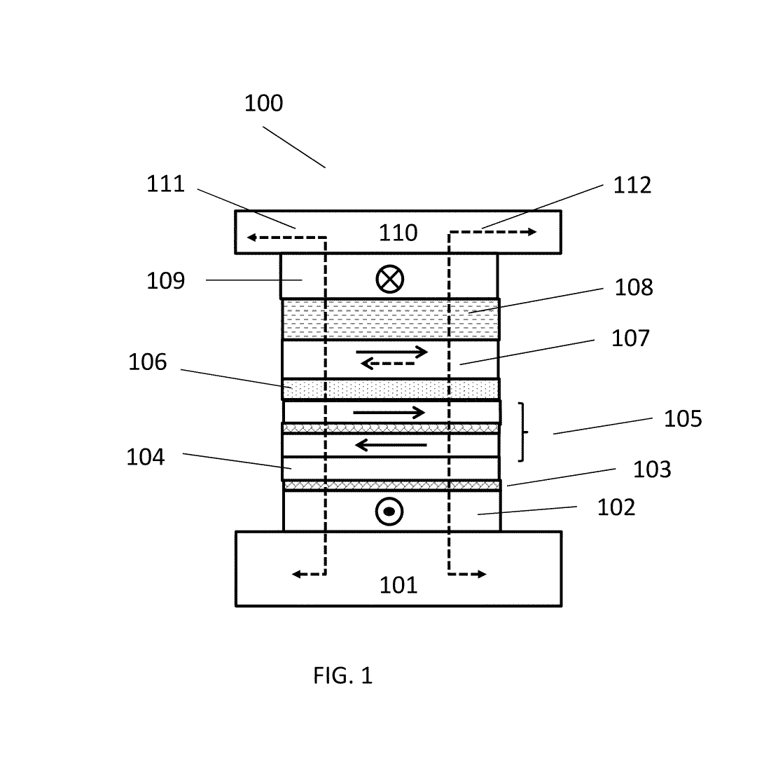

With reference of the FIG. 1 shows an embodiment of proposed magnetic memory cell 100. The proposed MRAM memory cell 100, counted from the material growth plane from the bottom, comprises a bottom electrode 101; in-plane-anisotropy magnetic stabilization layer 102 with fixed magnetization orientation; an non-magnetic metallic layer 103; antiferromagnetic layer 104 such as IrMn; synthetic antiferromagnetic layer (SAF) 105 with balanced or closely balanced moment for magnetic layers (for example CoFeB20/CoFe10/Ru/CoFe10/CoFeB20); tunneling barrier 106 such as MgO, TiOx, AlOx; in-plane anisotropic data storage layer 107 such as CoFeB; non-magnetic metallic layer 108 with long spin diffusion length such as Cu, Al; in-plane-anisotropy stabilization layer 109 with fixed magnetization orientation and top electrode 110. The magnetic stabilization layer 102 and 109 have their magnetizations pointing at opposite direction and being normal to the magnetization of magnetic layers in SAF layer 105. The net magnetic moment of the layer 102 and 109 prefers to be very close or the same amount so that they can form a flux close loop with edge magnetic charge canceling each other. If the magnetic moment of layer 102 and 109 is not the same, the individual distance from the layer 102 or layer 109 to the data storage layer 107 need to be adjusted accordingly to ensure the force acts on the data storage layer from the layer 102 and layer 109 is close to balance. By doing so, an energy barrier is established along the direction normal to the magnetization of magnetic layers in SAF layer 105, which prohibits the magnetization of data storage layer 107 to align into this direction at static state because this breaks the magnetic balance and established close flux loop between the layer 102 and 109. As such, we use the in-stack layer 102 and 109 to establish a magnetic anisotropy in the memory cell structure, which can enhance the magnetic stability against thermal agitation. Since the magnetizations of layer 102 and 109 need point to opposite direction, the coercivity of layer 102 and 109 should be significantly different so that the magnetizations of layer 102 and 109 can be set independently by external field with little interference. The layer 102 can be made of the hard magnetic materials such as CoCr, CoPt, CoCrPt or bilayer or multilayer comprising soft magnetic layer and hard magnetic layer such as CoPt/CoFe, CoCrPt/NiFe etc. For layer 109, it is preferable to be made of bilayer or multilayer comprising soft magnetic layer and hard magnetic layer such as CoPt/CoFe, CoCrPt/NiFe etc because the layer 109 can also act as a spin polarization layer for write current 111. As said previously, a non-magnetic metallic layer 108 is made of long spin diffusion length such as Cu, Al separating the layer 109 from the data storage layer 107. When the write current 111 through layer 109 get polarized, the polarized write current 111 will preserve this polarized state when move into the data storage layer 107. Based on theory [1,2,8], the magnetization of data storage layer 107 will be switched direction. This reduces the critical current needed to flip the data storage layer 107 comparing to a based MTJ at the same conditions.

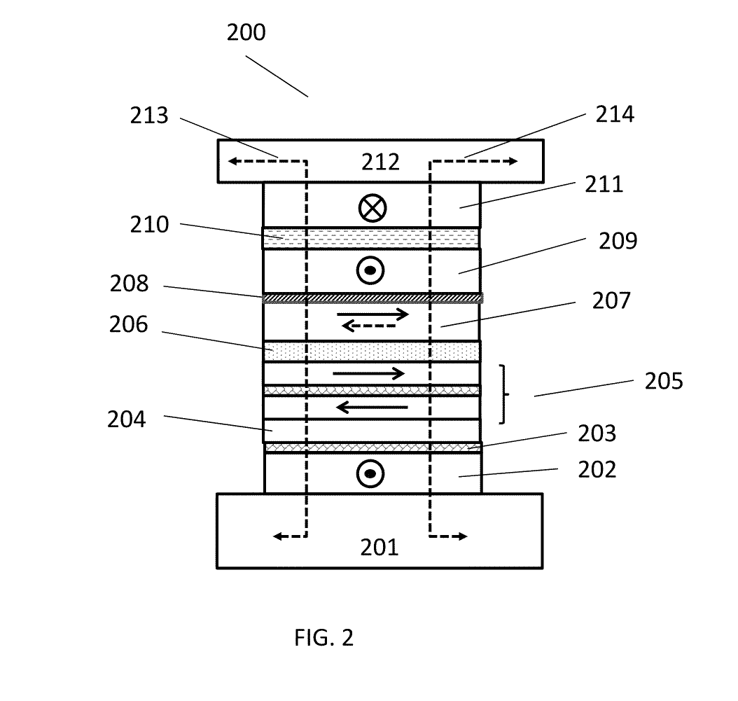

With reference of the FIG. 2 shows an embodiment of proposed magnetic memory cell 200, the proposed MRAM memory cell 200, counted from the bottom, comprises a bottom electrode 201; in-plane-anisotropy magnetic stabilization layer 202 with fixed magnetization orientation; an non-magnetic metallic layer 203; antiferromagnetic layer 204 such as IrMn; synthetic antiferromagnetic layer (SAF) 205 with balanced or closely balanced moment for magnetic layers; tunneling barrier 206 such as MgO, TiOx, AlOx ; in-plane anisotropic data storage layer 207 such as CoFeB; non-magnetic dielectric layer 208 such as MgO, TiOx, AlOx or the combination of dielectric with metal such as Cu, Al, Ag such as MgO/Cu with significant low value of resistance-area product RA compared to the barrier 206; fixed in-plane-anisotropy spin polarization layer 209; metallic spacer layer 210; fixed in-plane-anisotropy stabilization layer 211 and top electrode 212.

The magnetic stabilization layer 202 and 211 has their magnetizations pointing at opposite direction and being normal to the magnetization of magnetic layers in SAF layer 205. The magnetization of the spin polarization 209 also points to opposite to that of the stabilization layer 211 with the moment of the layer 211 is noticeably larger than that of layer 209. Overall, the design of the materials of layers 202, 209 and 211 follows the rule that the data storage data 207 sees balanced magnetic torque from layer 202, 209 and 211 when it slightly rotates from its stable positions. One of the way to achieve the design rule is to balance the overall distance between the data storage layer 207 to layer 209, 211 and 202 and keep overall the net moment of these three layers, considering the orientation of the magnetization of each layer, is zero or very close to zero so that they can form a flux close loop with edge magnetic charge canceling each other. The layer 210 separates the layer 211 from the spin polarization layer 209 and can be made of metallic layer with short pin diffusion length. The thickness of layer 210 need to large enough to destroy the spin memory of the electrons obtained from the magnetic layer 211.

The layer 202 and 211 can be made of the hard magnetic materials such as CoCr, CoPt, CoCrPt or bilayer or multilayer comprising soft magnetic layer and hard magnetic layer such as CoPt/CoFe, CoCrPt/NiFe etc. For layer 209, it is preferable to be made of bilayer or multilayer comprising soft magnetic layer and hard magnetic layer such as CoPt/CoFeB, CoCrPt/CoFeB etc because the layer 209 is a fixed spin polarization layer for write current 213.

As said previously, non-magnetic layer 208 is made of MgO, TiOx, AlOx or the combination of dielectric with metal such as Cu, Al, Ag such as MgO/Cu with significant low value of resistance-area product RA compared to the barrier 206. When the write current 213 through layer 209 get polarized, the polarized write current 213 will preserve this polarized state when move into the data storage layer 207. Based on theory [1,2,8], the magnetization of data storage layer 207 will be switched direction. This reduces the critical current needed to flip the data storage layer 207 comparing to a based MTJ at the same conditions.

Layers 208, 209 and 210 build up the separating layer between the layer 211 and data storage layer 207.

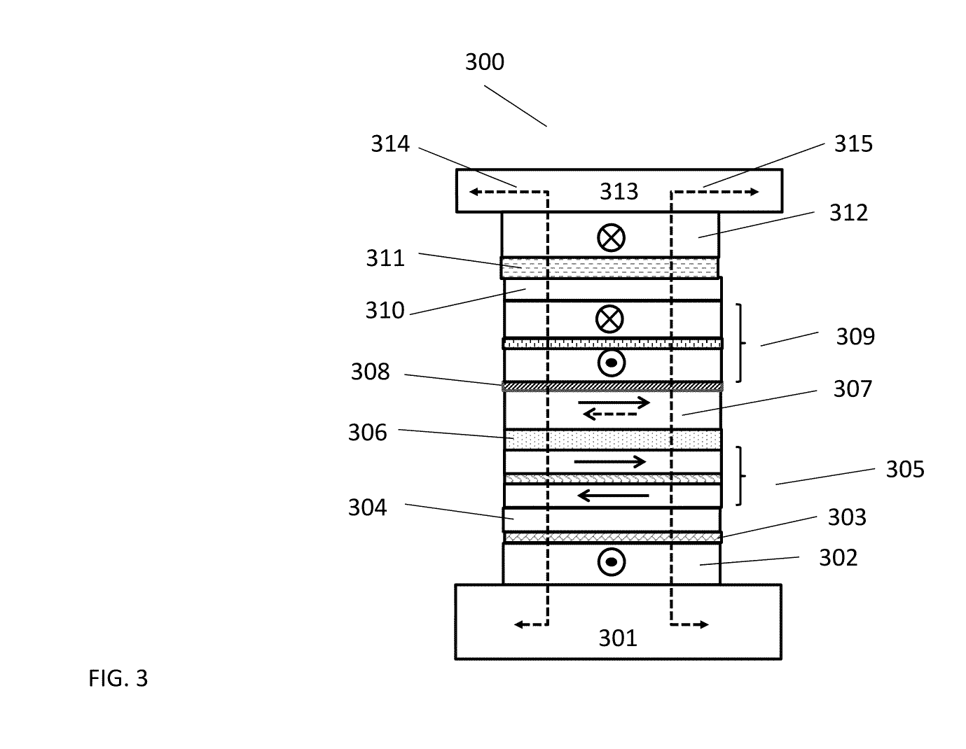

FIG.3 shows an embodiment of proposed a magnetic memory cell 300. the proposed MRAM memory cell 300, counted from the bottom, comprises a bottom electrode 301; in-plane-anisotropy magnetic stabilization layer 302 with fixed magnetization orientation; an non-magnetic metallic layer 303; antiferromagnetic layer 304 such as IrMn; synthetic antiferromagnetic layer (SAF) 305 with balanced or closely balanced moment for magnetic layers; tunneling barrier 306 such as MgO, TiOx, AlOx ; in-plane anisotropic data storage layer 307 such as CoFeB; non-magnetic layer 308 such as MgO, TiOx, AlOx or the combination of dielectric with metal such as Cu, Al, Ag such as MgO/Cu with significant low value of resistance-area product RA compared to the barrier 306; a SAF spin polarization layer 309 with structure such as CoFe/Ru/CoFe; a SAF polarizer stabilizing layer 310; an metallic spacer layer 311; a fixed in-plane-anisotropy stabilization layer 312 and top electrode 213.

The magnetic stabilization layer 302 and 312 has their magnetizations pointing at opposite direction and being normal to the magnetization of magnetic layers in SAF layer 305.

The magnetization directions of the magnetic layers for the SAF spin polarization layer 309 points also normally to the magnetization of magnetic layers in SAF layer 305. SAF polarizer stabilizing layer 310 is above the SAF spin polarization layer and it can be made of either permanent magnetic layer such as CoPt or CoCr-based hard magnetic layer or antiferromagnetic layer such as IrMn or PtMn, whose Neel temperature is significantly different from the one of the layer 304. Regardless of the materials used for layer 310, the design rule is that the magnetic moment from layer 309 and layer 310 on both sides of the Ru layer in SAF layer 309 should be equal or very closely to be equal. As such, the magnetic layers, including layer 310, on both sides of the Ru layer of SAF layer 309 will form a close flux loop and give zero combined edge magnetic charges.

The layer 311 separates the layer 312 from the layer 310 and can be made of metallic layer with short pin diffusion length. The thickness of layer 311 need to large enough to destroy the spin memory of the electrons obtained from the magnetic layer 312.

The layer 302 and 312 can be made of the hard magnetic materials such as CoCr, CoPt, CoCrPt or bilayer or multilayer comprising soft magnetic layer and hard magnetic layer such as CoPt/CoFe, CoCrPt/NiFe etc. The coercivity of layer 302 and layer 312 need widely different so that they can be set by external magnetic field independently.

As said previously, non-magnetic layer 308 is made of MgO, TiOx, AlOx or the combination of dielectric with metal such as Cu, Al, Ag such as MgO/Cu with significant low value of resistance-area product RA compared to the barrier 306. When the write current 314 through layer 309 get polarized, the polarized write current 314 will preserve this polarized state when move into the data storage layer 307. Based on theory [1,2,8], the magnetization of data storage layer 307 will be switched direction. This reduces the critical current needed to flip the data storage layer 307 comparing to a based MTJ at the same conditions.

Layers 308, 309, 310 and 311 build up the separating layer between the layer 312 and data storage layer 307.

What is claimed is:

1. A magnetic memory device, comprising:
a magnetic tunneling junction (MTJ), which comprises a fixed magnetic reference layer with in-plane-anisotropy; an in-plane-anisotropy magnetic data storage layer, whose magnetization can rotate, and a dielectric tunneling barrier;
a fixed in-plane-anisotropy magnetic layer 1 magnetically separated away from the data storage layer of MTJ and locates on one side of said data storage layer. The magnetization of the layer 1 is normal to the magnetization of the reference layer of MTJ;
a fixed in-plane-anisotropy magnetic layer 2 magnetically separated away from said storage layer of MTJ and locates on the other side of said data storage layer. The magnetization of the layer 2 is also normal to the magnetization of said reference layer of MTJ and is opposite to the magnetization of said layer 1;
Said layer 1 and said layer 2 assist to stabilize said data storage layer of MTJ.

2. The magnetic memory device of claim 1, wherein said reference layer comprises a balanced or closely balanced synthetic antiferromagnetic layers.

3. The magnetic memory device of claim 1, wherein the coercivity of said layer 1 and said layer 2 should be distinctively different and have predetermined large separation so that the magnetization of said layer and said layer 2 can be set by external magnetic field independently.

4. The magnetic memory device of claim 1, wherein either said layer 1 or said layer 2 is separated away from said data storage layer only by a single non-magnetic metallic layer, whose spin diffusion length is relatively long, for example, Cu, Ag, Al, Au or their combinations.

5. The magnetic memory device of claim 4, wherein said layer 1 and said layer 2, can be made of hard magnetic layer such as CoPt, CoCr or the combination of hard magnetic layer and high moment soft magnetic layer, which locates adjacent to the non-magnetic metallic layer and have capability of high spin polarization, for example CoPt/CoFe, CoCrPt/Co Fe.

6. The magnetic memory device of claim 4, wherein the magnitude of the magnetic moment of said layer 1, said layer 2 and said data storage layer prefer to be the same or very close.

7. The magnetic memory device of claim 1, wherein the layer among said layer 1 and said layer 2, which locates on the same side as said data storage layer relative to said dielectric tunneling barrier, can be separated away from said data storage layer by a space layer, a fixed magnetic layer over the space layer and a metallic spacer.

8. The magnetic memory device of claim 7, wherein said space layer is adjacent to said data storage layer and can be made of MgO, TiOx, AIOx or CrOx or combination of dielectric with metal such as Cu, Al, Ag such as MgO/Cu, with product of resistance and area (RA) being significant lower than that of said dielectric tunneling barrier.

9. The magnetic memory device of claim 7, wherein said metallic spacer separates said fixed magnetic layer over said space layer from said layer among said layer 1 and said layer 2.

10. The magnetic memory device of claim 7, wherein said metallic spacer can be made of heavy metal layer with short spin diffusion length such as Ta.

11. The magnetic memory device of claim 7, wherein said fixed magnetic layer over said space layer can be made of the combination of hard magnetic layer and high moment soft magnetic layer such as CoPt/CoFe, CoCrPt/CoFe, CoCr/CoFe, whose magnetization is opposite to that of said layer among said layer 1 and said layer 2.

12. The magnetic memory device of claim 7, wherein the coercivity of said fixed magnetic layer over said space layer should be distinctively different and have pre-determined large separation from that of said layer among said layer 1 and said layer 2.

13. The magnetic memory device of claim 1, wherein the layer among said layer 1 and said layer 2, which locates on the same side as said data storage layer relative to said dielectric tunneling barrier, can be separated away from said data storage layer by a space layer, a fixed synthetic antiferromagnetic layer over the space layer and a metallic spacer.

14. The magnetic memory device of claim 13, wherein said space layer is adjacent to said data storage layer and can be made of MgO, TiOx, AIOx or CrOx or combination of dielectric with metal such as Cu, Al, Ag such as MgO/Cu, with product of resistance and area (RA) being significant lower than that of said dielectric tunneling barrier.

15. The magnetic memory device of claim 13, wherein said metallic spacer separates said fixed synthetic antiferromagnetic layer over the space layer from said layer among said layer 1 and said layer 2.

16. The magnetic memory device of claim 13, wherein said metallic spacer can be made of heavy metal layer with short spin diffusion length such as Ta.

17. The magnetic memory device of claim 13, wherein said fixed synthetic antiferromagnetic layer over said space layer is made of a metal layer sandwiched between two moment balanced or closely balanced magnetic layers, whose magnetization are normal to that of said reference layer of MTJ.

18. The magnetic memory device of claim 17, wherein said metal layer can introduce RKKY coupling between the magnetic layers on both sides.

19. The magnetic memory device of claim 17, wherein one of the magnetic layers comprises hard magnetic layer such as CoCrPt, CoCr or CrPt.

20. The magnetic memory device of claim 17, wherein an example of said fixed synthetic antiferromagnetic layer over said space layer can be CoFe/Ru/CoFe/CoPt.

21. The magnetic memory device of claim 17, one of the magnetic layer of said fixed synthetic antiferromagnetic layer is adjacent to an antiferromagnetic layer such as IrMn and its magnetization is pinned by said antiferromagnetic layer.
